(19) United States
(12) Patent Application Publication
(10) Pub. No.: US 2026/0190293 A1
(43) Pub. Date: Jul. 2, 2026

(54) POWER TOOL WITH HOUSING PROVIDING CIRCUIT BOARD COOLING

(71) Applicant: Robert Bosch GmbH, Stuttgart (DE)

(72) Inventors: Stephen Claude Oberheim, Arlington Heights, IL (US); Peter Jack Wierzchon, Morton Grove, IL (US); Eric Mallory, Naperville, IL (US)

(21) Appl. No.: 19/004,274

(22) Filed: Dec. 28, 2024

(51) Int. Cl. H05K 7/20; B25F 5/00; B27C 5/10; H05K 7/14

(52) U.S. Cl. CPC H05K 7/2039; B25F 5/008; H05K 7/20136; B27C 5/10; H05K 7/1427

(57) ABSTRACT

A power tool includes a metallic housing having a user-facing first side portion and a second side portion opposite the user-facing first side portion. The metallic housing defines a cooling zone in the second side portion opposite the user-facing first side portion, and a circuit board assembly is mounted to the cooling zone in thermal communication with the cooling zone. A motor is positioned within the metallic housing at a location between the circuit board assembly and the user-facing first side portion.

### FIELD

The present disclosure relates generally to power tools and more specifically to power tools including heat generating circuit boards.

### BACKGROUND

Modern cordless power tools utilize brushless DC motors (BLDC) which provide high power density, low weight, and don't require brush changes. BLDC motors require drive electronics to control the timing and amount of power to the motor windings in order to control the direction and speed of motor rotation. The drive electronics control significant amounts of power and utilize power control components such as MOSFETs. Consequently, because the MOSFETs handle significant amounts of power, there is a significant need for heat dissipation to reduce the potential for damage to the MOSFETs.

As a precaution against heat damage to the MOSFETS, on board temperature sensing is typically employed and the entire board is turned off automatically by protection circuits if the MOSFETs get too hot. While effective in protecting against damage to the MOSFETS, this approach abruptly shuts off the power tool which can be very disruptive and annoying to a user if it occurs, for instance, in the middle of a precision cut, especially when the cut involves expensive wood. Even if the wood is not expensive or difficult to acquire, if the disruption occurs in a critical location the wood may need to be replaced which may result in significant delays as the user re-orders the wood. At a minimum, once the protective circuit interrupts power the user will have to wait for the tool electronics to cool off and resume the precision cut, usually with significant impact on cut quality and appearance. In addition to user inconvenience, the power tool manufacturer may suffer since this type of interruption can lead to a low star rating for the tool in buyer forums and a poor reputation in the trade.

What is needed is a system which reduces one or more of the issues discussed above.

### SUMMARY

The disclosure provides power tool with a good thermal connection between a circuit board and a metal housing. Low cost and advantageous heat removal is achieved due to the presence of a large thermal mass (the housing) and the proximity of an external surface providing convective and radiative cooling. Because of the enhanced cooling, the power tool does not require an additional heat sink or fans to achieve heat removal from the circuit board assembly. Cooling is achieved economically by removal of heat from the circuit board by thermal conduction and convection utilizing the cast housing. The housing provides a large thermal mass with good heat conduction properties. This large thermal mass soaks up heat from the circuit board assembly, significantly reducing any temperature rise of the circuit board. Additionally, the housing has exterior surfaces which transfer heat into the external air surrounding the power tool through convection and radiation. The convective transfer of heat from the housing to the air is enhanced in some embodiments using a set of fin shapes cast with the housing. Radiative heat transfer from the housing in some embodiments is augmented by painting the radiating area black (to increase infrared heat emission—as in black body emissivity).

In some embodiments, a power tool includes a metallic housing having a user-facing first side portion and a second side portion opposite the user-facing first side portion. The metallic housing defines a cooling zone in the second side portion opposite the user-facing first side portion, and a circuit board assembly is mounted to the cooling zone in thermal communication with the cooling zone. A motor is positioned within the metallic housing at a location between the circuit board assembly and the user-facing first side portion.

In some embodiments the circuit board assembly includes a frame, a metal plate, and a circuit board. The frame defines at least in part a cavity. The metal plate is attached to the frame and has a first heat transfer side defining at least in part an outer surface of the circuit board assembly and a second heat transfer side facing toward the cavity. The second heat transfer side is in thermal communication with the cooling zone through the first heat transfer side, and the circuit board is in thermal communication with the first heat transfer side through the second heat transfer side.

In some embodiments the motor defines a motor axis and the circuit board includes at least one MOSFET. The second heat transfer side is directly between a first of the at least one MOSFET and the first heat transfer side in a plane orthogonal to the motor axis.

In some embodiments the cooling zone includes a first cooling zone side to which the circuit board assembly is mounted and a second cooling zone side opposite to the first cooling zone side. A plurality of fins extends from the second cooling zone side in a direction away from the circuit board assembly, and at least a portion of the plurality of fins is coplanar with the circuit board assembly in the plane orthogonal to the motor axis.

In some embodiments the plurality of fins is at least one of painted black and black anodized.

In some embodiments the metallic housing incudes a generally circular portion and an extension. The extension includes a generally planar portion facing the motor, and the circuit board assembly is mounted to the generally planar portion.

In some embodiments the plurality of fins extends from the second cooling zone side toward the motor.

In some embodiments the plurality of fins extends from the second cooling zone side away from the motor.

In some embodiments a first handle is supported by the metallic housing, a second handle supported by the metallic housing, and the metallic housing is located between the first handle and the second handle. At least a portion of the first handle is coplanar with the circuit board assembly in the plane orthogonal to the motor axis, and at least a portion of the second handle is coplanar with the circuit board assembly in the plane orthogonal to the motor axis.

In some embodiments a fan is driven by the motor and configured to generate an airflow within the metallic housing. At least one vent is located at a lower portion of the power tool and configured to allow air to flow from outside of the metallic housing through the at least one vent and into the metallic housing. The airflow including the air flowing through the at least one vent is directed by the at least one vent to flow through the plurality of fins or across the circuit board assembly from a lower portion of the circuit board assembly to an upper portion of the circuit board assembly.

In some embodiments the circuit board assembly further includes a heat spreader plate including a base contact portion in thermal communication with a second of the at least one MOSFET, and includes a cooling fin extending into the airflow.

In some embodiments a method of cooling a power tool includes providing a metallic housing having a user-facing first side portion and a second side portion opposite the user-facing first side portion, the metallic housing defining a cooling zone in the second side portion opposite the user-facing first side portion, and mounting a circuit board assembly to the cooling zone such that the circuit board assembly is in thermal communication with the cooling zone with a motor positioned within the metallic housing at a location between the circuit board assembly and the user-facing first side portion. The method includes generating heat with the circuit board assembly, and transferring the generated heat to the cooling zone.

In some embodiments the circuit board assembly includes a frame, a metal plate, and a circuit board. The frame defines at least in part a cavity, the metal plate is attached to the frame and has a first heat transfer side defining at least in part an outer surface of the circuit board assembly and a second heat transfer side facing toward the cavity, the second heat transfer side is in thermal communication with the cooling zone through the first heat transfer side, and the circuit board is in thermal communication with the first heat transfer side through the second heat transfer side. The generating the heat with the circuit board assembly includes generating heat with at least one circuit board component, and transferring the generated heat to the cooling zone includes transferring the heat generated by the at least one circuit board component from the circuit board to the first heat transfer side from the second heat transfer side.

In some embodiments the method is performed using a power tool wherein the motor defines a motor axis, the circuit board includes at least one MOSFET, the second heat transfer side is directly between the at least one MOSFET and the first heat transfer side in a plane orthogonal to the motor axis, and the at least one circuit board component includes the at least one MOSFET.

In some embodiments wherein the cooling zone includes a first cooling zone side to which the circuit board assembly is mounted and a second cooling zone side opposite to the first cooling zone side, a plurality of fins extends from the second cooling zone side in a direction away from the circuit board assembly, at least a portion of the plurality of fins is coplanar with the circuit board assembly in the plane orthogonal to the motor axis the method further includes transferring heat from the cooling zone using the plurality of fins.

In some embodiments the method is performed using a tool wherein the plurality of fins is at least one of painted black and black anodized.

In some embodiments wherein the metallic housing incudes a generally circular portion and an extension, the extension includes a generally planar portion facing the motor, and the circuit board assembly is mounted to the generally planar portion, the method includes transferring the generated heat to the cooling zone by transferring the generated heat to the generally planar portion.

In some embodiments transferring heat from the cooling zone using the plurality of fins includes transferring the heat from the cooling zone into a motor cavity of the metallic housing.

In some embodiments transferring heat from the cooling zone using the plurality of fins includes transferring the heat from the cooling zone into an environment surrounding the metallic housing.

In some embodiments the method further includes directing an airflow generated by a fan driven by the motor through the plurality of fins or across the circuit board assembly from a lower portion of the circuit board assembly to an upper portion of the circuit board assembly.

### BRIEF DESCRIPTION OF THE DRAWINGS

The above-described features and advantages, as well as others, will become more readily apparent to those of ordinary skill in the art by reference to the following detailed description and accompanying drawings.

FIG. 1 depicts a perspective view of a user-facing side of a power tool configured as a plunge router;

FIG. 2 depicts a perspective view of the side opposite the user-facing side of the power tool of FIG. 1;

FIG. 3 depicts a top perspective view of the metallic housing of the embodiment of FIG. 1 with a circuit board assembly and a motor installed;

FIG. 4 depicts a partial side perspective cross-sectional view of the metallic housing of the embodiment of FIG. 1 with a circuit board assembly and a motor installed;

FIG. 5 depicts a bottom perspective view of a metal insert of the circuit board assembly of FIG. 3;

FIG. 6 depicts a top perspective view of the metal insert of FIG. 5 inserted within a frame member of the circuit board assembly of FIG. 3;

FIG. 7 depicts a top perspective view of the frame member of FIG. 6;

FIG. 8 depicts bottom perspective view of the metal insert of FIG. 5 inserted within a frame member of the circuit board assembly of FIG. 3;

FIG. 9 depicts a top perspective view of a circuit board of the circuit board assembly of FIG. 3;

FIG. 10 depicts a top perspective view of the circuit board of FIG. 9 mounted within the frame of FIG. 7;

FIG. 11 depicts a top perspective view of the circuit board assembly of FIG. 3 including a heat spreader plate;

FIG. 12 depicts a top plan view of the circuit board assembly of FIG. 3 including the heat spreader plate;

FIG. 13 depicts a partial side perspective cross-sectional view of the metallic housing of the embodiment of FIG. 1 with a circuit board assembly and a motor installed;

FIG. 14 depicts a side cross-sectional view of the power tool of FIG. 1 showing a cooling modality provided when the motor is running;

FIG. 15 depicts a side cross-sectional view of the power tool of FIG. 1 showing a cooling modality provided when the motor is not running; and

FIG. 16 depicts a partial top perspective view of an alternative embodiment wherein the cooling fins are located within the metallic housing and the circuit board assembly is mounted on an external side of the metallic housing.

### DETAILED DESCRIPTION

For the purpose of promoting an understanding of the principles of the disclosure, reference will now be made to the embodiments illustrated in the drawings and described in the following written description. It is to be understood that no limitation to the scope of the disclosure is thereby intended. It is further to be understood that the present disclosure includes any alterations and modifications to the illustrated embodiments and includes further applications of the principles of the disclosure as would normally occur to one skilled in the art to which this disclosure pertains.

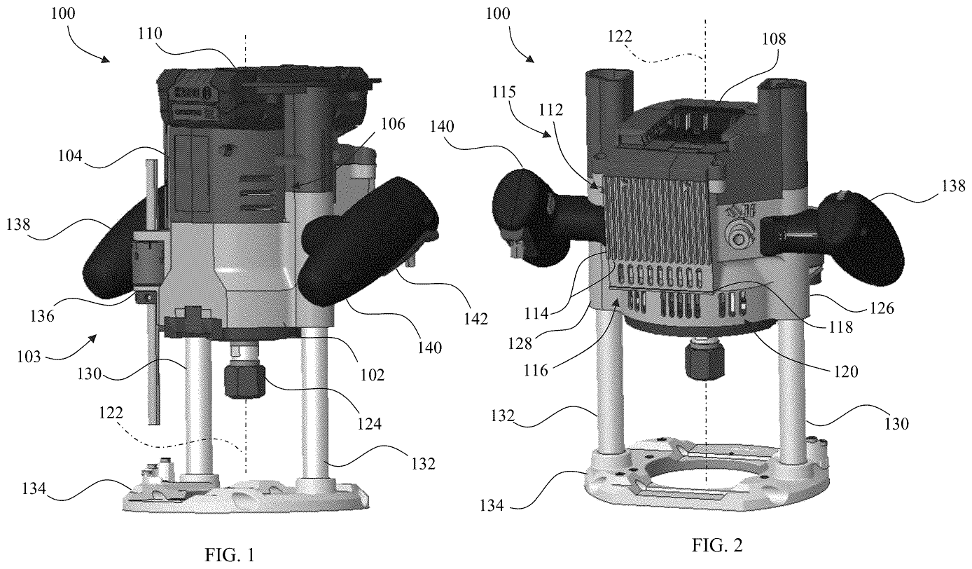

FIGS. 1 and 2 depict a power tool 100, which in this embodiment is configured as a plunge router, which includes a metallic housing 102 and an upper housing 104. The upper housing 104 includes a plurality of upper inlet vents 106 on a user-facing side portion 103 of the power tool 100, and a battery receptacle 108 which is configured to receive a battery 110. In other embodiments the power tool 100 is configured to be powered by a wired power supply.

The metallic housing 102 includes a cooling zone 112 including a plurality of cooling fins 114 on a side portion 115 of the power tool 100 opposite the user-facing side portion 103. A “cooling zone” as that term is used herein is defined as a portion of the metallic housing of a power tool which receives heat energy from a circuit board assembly, by conduction, either directly from the circuit board assembly or by way of an intermediate member so long as the intermediate member is not a part of the metallic housing. The plurality of cooling fins 114 in some embodiments are integrally formed with the metallic housing 102 during a casting process of the metallic housing 102. This is particularly well-suited for embodiments wherein the metallic housing 102 is die cast from aluminum.

Located beneath the plurality of cooling fins 114 are a plurality of lower inlet vents 116. A gurney lip 118 is located beneath the plurality of lower inlet vents 116 and above a plurality of outlet vents 120. The plurality of outlet vents 120 are inwardly offset from the gurney lip 118. Both the plurality of lower inlet vents 116 and the plurality of outlet vents 120 are located beneath the plurality of upper inlet vents 106 along a motor axis 122 of the power tool 100 defined by an output shaft assembly 124.

The metallic housing 102 further includes plunger rod support 126 and plunger rod support 128 from which plunger rod 130 and plunger rod 132, respectively, extend. Lower ends of the plunger rod 130 and plunger rod 132 are connected to a base 134. The plunger rod support 126 includes a plunge depth adjustment assembly 136. A handle 138 and a handle 140 are supported by the metallic housing 102. A power button 142 is positioned on the handle 140.

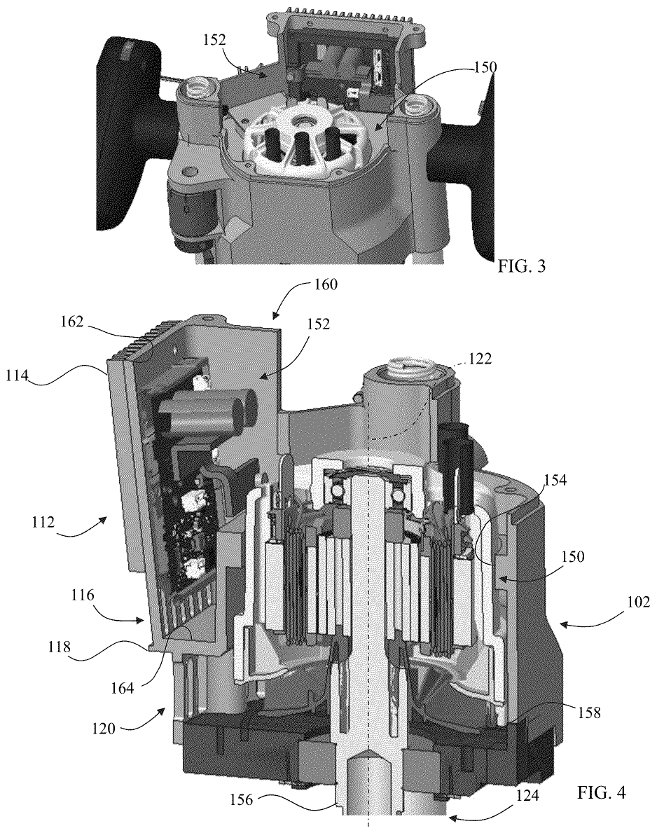

The power button 142 is used to control power to a brushless DC motor (BLDC) 150 through a circuit board assembly 152 shown in FIGS. 3 and 4. The BLDC 150 is positioned within a generally circular motor cavity 154 of the metallic housing 102. The BLDC 150 includes an output shaft 156 which is part of the output shaft assembly 124. A fan 158 is fixedly attached to the output shaft 156.

The circuit board assembly 152 is positioned within an extension 160 of the metallic housing 102. The extension 160 includes the plurality of lower inlet vents 116 and a generally planar portion 162 located above the plurality of lower inlet vents 116. The generally planar portion 162 is formed with a large “draft” angle of up to about 6 degrees. This angle ensures consistent tooling release and the flatness provides good bonding with the circuit board assembly 152. Inclining the circuit board assembly 152 allows for packaging of capacitors over any locking linkage, allowing for a more compact package. In some embodiments tabs are cast into the generally planar portion 162 to facilitate positioning of the circuit board assembly 152 on the cooling zone 112.

A floor 164 is substantially coplanar with the bottoms of the plurality of lower inlet vents 116. In some embodiments, the floor 164 is slightly canted in a direction upwardly and away from the bottom of the plurality of lower inlet vents 116 in a direction toward the motor axis 122. The gurney lip 118 extends radially outwardly from the metallic housing 102, and in some embodiments is slightly canted downwardly and away from the metallic housing 102.

The circuit board assembly 152 is mounted to the generally planar portion 162 so as to be in thermal communication with the metallic housing 102. The circuit board assembly 152 is described in further detail with reference to FIGS. 5-12. The circuit board assembly 152 includes a metal insert 170 shown in FIG. 5. The metal insert 170 includes a raised contact portion 172 which is configured to extend within a heat transfer window 174 of a frame member 176 as shown in FIG. 6. Frame member 176 is further shown in FIG. 7 and defines a cavity 177. In some embodiments the frame member 176 is insert molded with the metal insert 170. The metal insert 170 is positioned within an insert window 178 of the frame member 176 such that a base portion 180 of the metal insert 170 is substantially coplanar with the bottom 182 of the frame member 176 as shown in FIG. 8. This provides good thermal contact with the generally planar portion 162. The insert window 178 is partially separated from the cavity 177 by a lip 179 (see FIG. 6) which defines the heat transfer window 174.

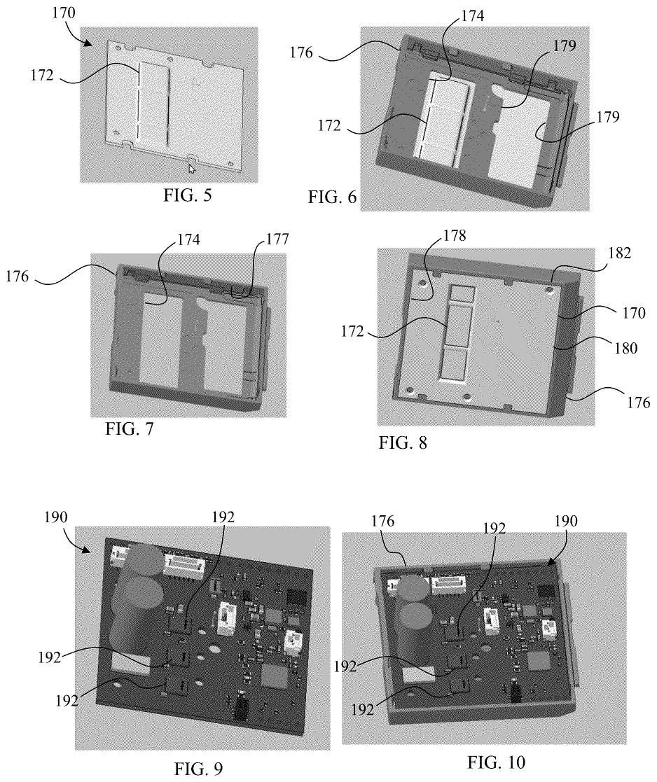

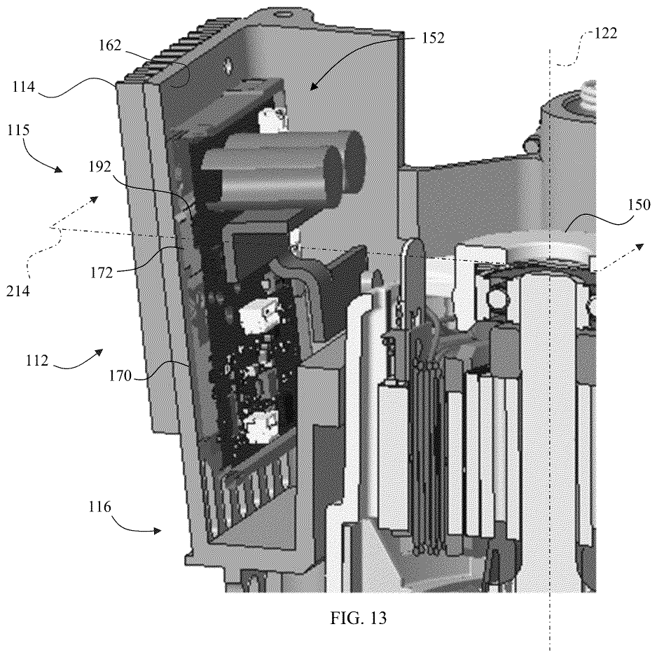

The circuit board assembly 152 further includes a circuit board 190 shown in FIG. 9. The circuit board 190 includes a number of circuit board components including MOSFETS 192. The MOSFETS 192, which in one embodiment includes three MOSFETS 192 mounted on the top of the circuit board 190 and an additional three mounted on the bottom of the circuit board 190 (see FIG. 13), generate most of the heat generated by the circuit board 190. In other embodiments fewer or more MOSFETS are provided. So as to provide cooling of the circuit board 190, and in particular the MOSFETS 192, the lower MOSFETS 192 are positioned so as to be in thermal communication with the raised contact portion 172 when the circuit board 190 is mounted within the frame member 176 as shown in FIG. 10. In some embodiments, thermal paste is positioned between the lower MOSFETS 192 and the raised contact portion 172 to encourage thermal communication. Thermal paste is further used in some embodiments between the metal insert 170 and the generally planar portion 162 for the same purpose.

Typically, a potting material is used to fill the frame member 176 so as to protect the components on the circuit board 190. The potting material may flow between the bottom of the circuit board 190 and the base portion 180. Thus, while the raised contact portion 172 provides good thermal communication with the MOSFETS 192 located on the bottom of the circuit board 190, the potting material may inhibit cooling of the MOSFETS 192 on the top o the circuit board 190.

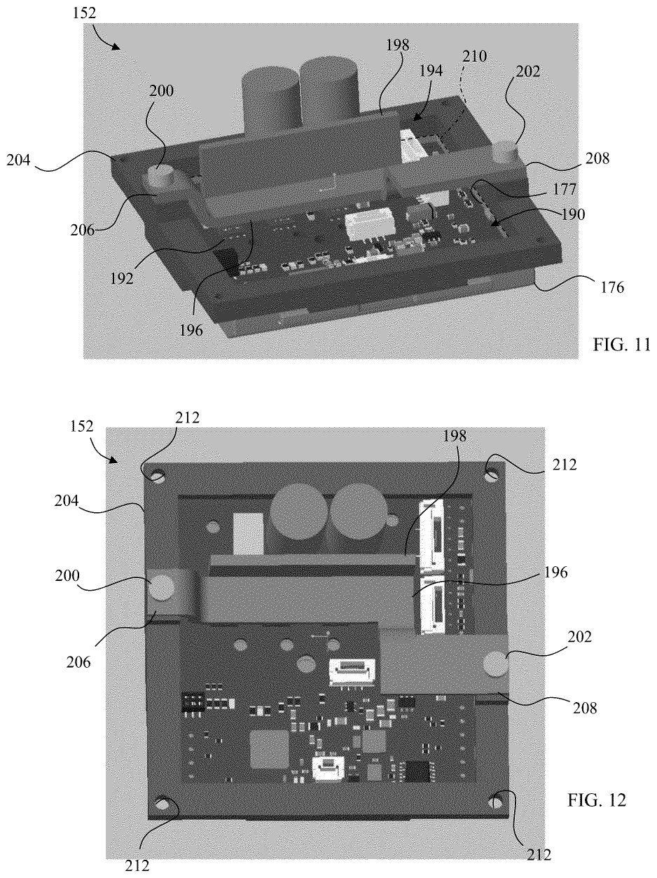

Accordingly, in some embodiments cooling is provided through the circuit board 190 such as by providing for thermal communication between the MOSFETS 192 on the top of the circuit board 190 and the raised contact portion 172 or base portion 180 through the circuit board 190. In the embodiment of FIG. 1 cooling is additionally and/or alternatively provided by a heat spreader plate 194 shown in FIGS. 11 and 12.

The heat spreader plate 194 includes a base contact portion 196 and an upwardly extending cooling fin 198. The heat spreader plate 194 is mounted using a mounting pin 200 and a mounting pin 202 to a spreader plate mount 204 by a mounting portion 206 and a mounting portion 208, respectively. The base contact portion 196 is in thermal communication with the MOSFETS 192 on the upper side of the circuit board 190, in some instances, through a thermal paste. The cooling fin 198 is configured to extend outwardly of a potting material 210 filling the cavity 177. In some embodiments, an upper surface of the base contact portion 196 is also located outside of the potting material. Four mounting holes 212 in the spreader plate mount 204 are used to mount the circuit board assembly 152 to the generally planar portion 162.

The power tool 100 provides for three cooling modalities. A first cooling modality is described with reference to FIG. 13 which shows the circuit board assembly 152 mounted to the cooling zone 112. In this modality, which functions both when the BLDC 150 is operating and when the BLDC 150 is not operating, any heat presently or previously generated by the MOSFETS 192 on the bottom of the circuit board assembly 152 is transferred to an inwardly facing heat transfer side of the raised contact portion 172. To this end, the MOSFETS 192 on the outward side of the circuit board assembly 152 are coplanar with the raised contact portion 172 in a plane 214 orthogonal to the motor axis 122 so as to be directly radially inward of the raised contact portion 172. The heat is then transferred through the outwardly facing heat transfer side (bottom side as described in FIGS. 5-12) of the metal insert 170 into the cooling zone 112 of the metallic housing 102 through the generally planar portion 162 which functions as a heat transfer side of the extension 160. The heat passes through the metallic housing 102 and into the plurality of cooling fins 114 where it is dispersed to the environment surrounding the power tool 100. To aid in transfer of heat to the atmosphere the plurality of cooling fins 114 in some embodiments are painted black and/or black anodized.

The metallic housing 102 thus acts as a heat sink for the circuit board assembly 152. Moreover, since the metallic housing 102 is heated at a location which is in the side portion 115 which faces away from a user, and is not adjacent to the handle 138 or the handle 140, a user is less likely to inadvertently touch the heated cooling zone 112.

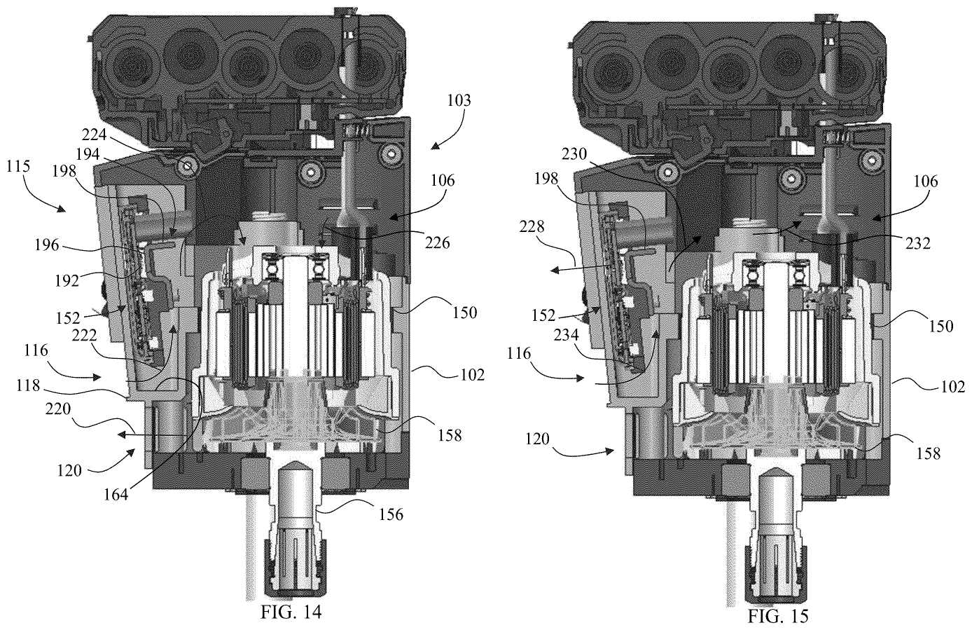

A second cooling modality is described with reference to FIG. 14. This modality provides cooling when the BLDC 150 is energized. In this modality, heat generated by the MOSFETS 192 on the inwardly facing side (the upper side as described in FIGS. 5-12) of the circuit board 190 is transferred to the base contact portion 196 of the heat spreader plate 194. The heat is then passed to the cooling fin 198. At the same time, the BLDC 150 is rotating and thus drives the fan 158 with the output shaft 156. The fan 158 forces air within the metallic housing 102 in the direction of the arrow 220 outwardly of the metallic housing 102 through the plurality of outlet vents 120.

Movement of the air outwardly of the metallic housing 102 though the plurality of outlet vents 120 causes a drop in pressure within the metallic housing 102 thereby drawing air from the environment into the metallic housing 102 through the plurality of lower inlet vents 116. The gurney lip 118 inhibits the air being drawn in through the plurality of lower inlet vents 116 from being the same air expelled through the plurality of outlet vents 120 to ensure cool air is moved in the direction of the arrow 222.

The airflow moving in the direction of the arrow 222 is primarily upward and the velocity is somewhat slow. Accordingly, any dust or debris in the airflow will typically not travel significantly upwardly. Rather, the dust or debris will collect on the floor 164. Because the floor 164 is substantially coplanar with the bottom of the plurality of lower inlet vents 116, the dust or debris will fall out of the plurality of lower inlet vents 116 during normal movement of the power tool 100.

As the air moves in the direction of the arrow 222, the air encounters the cooling fin 198 which has been heated by the MOSFETS 192. The cooling fin 198 introduces turbulence into the airflow increasing the efficiency of heat transfer from the 198, and in some instances the base contact portion 196, into the airflow. The air then continues to move in the direction of the arrow 224 into the BLDC 150. Some air is introduced into the airflow at the upper end of the BLDC 150 by the plurality of upper inlet vents 106 as indicated by the arrow 226. The plurality of upper inlet vents 106 and the plurality of lower inlet vents 116 are sized to provide a desired ratio of air drawn into the metallic housing 102 by the two vent groups to ensure desired cooling of the circuit board assembly 152. The airflow entering the BLDC 150 provides cooling of the BLDC 150 before being forced out of the metallic housing 102 through the plurality of outlet vents 120.

A third cooling modality is described with reference to FIG. 15. In this modality, the BLDC 150 is not energized. Accordingly, the fan 158 does not assist in cooling. The first cooling modality, however, continues as described above and thus heat is transferred out of the circuit board assembly 152 in the direction of the arrow 228 in the manner discussed above with respect to FIG. 13. Consequently, cooling of the MOSFETS 192 on the outwardly facing side of the circuit board 190 continues. Heat transfer from the MOSFETS 192 on the inwardly facing side of the circuit board 190 is enabled by the plurality of upper inlet vents 106.

In particular, as the cooling fin 198 receives heat from the MOSFETS 192, the cooling fin 198 heats the surrounding air causing the air to rise within the upper portion of the metallic housing 102. The heated air thus begins to further rise in the direction of the arrow 230. The airflow is not, however, drawn into the BLDC 150 by the fan 158 as in the modality of FIG. 14 since the fan 158 is not operating. Rather, the plurality of upper inlet vents 106 allow the heated air to move in the direction of the arrow 232 out of the metallic housing 102 through the plurality of upper inlet vents 106. Movement of the heated air out of the metallic housing 102 draws air into the metallic housing 102 through the plurality of lower inlet vents 116 generating a cool airflow in the direction of the arrow 234 toward the cooling fin 198. Some air may further flow through the plurality of outlet vents 120 to provide cooling for the BLDC 150. The system is configured, however, to ensure that at least some of the airflow is through the plurality of lower inlet vents 116.

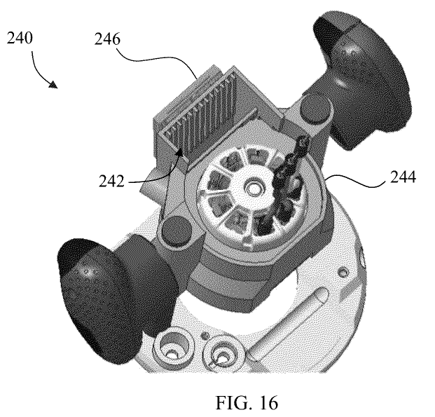

While the disclosure has been illustrated and described in detail in the drawings and foregoing description, the same should be considered as illustrative and not restrictive in character. It is understood that only the preferred embodiments have been presented and that all changes, modifications and further applications that come within the spirit of the disclosure are desired to be protected. By way of example, FIG. 16 depicts a portion of a power tool 240 which is substantially identical to the power tool 100. The difference is that in the power tool 240 the fins 242 are positioned within the metallic housing 244 while the circuit board assembly 246 is located on an outer side of the metallic housing 244.

What is claimed is:

1. A power tool comprising:
a metallic housing having a user-facing first side portion and a second side portion opposite the user-facing first side portion, the metallic housing defining a cooling zone in the second side portion opposite the user-facing first side portion;
a circuit board assembly mounted to the cooling zone and in thermal communication with the cooling zone; and
a motor positioned within the metallic housing at a location between the circuit board assembly and the user-facing first side portion.

2. The power tool of claim 1, wherein:
the circuit board assembly includes a frame, a metal plate, and a circuit board;
the frame defines at least in part a cavity;
the metal plate is attached to the frame and has a first heat transfer side defining at least in part an outer surface of the circuit board assembly and a second heat transfer side facing toward the cavity;
the second heat transfer side is in thermal communication with the cooling zone through the first heat transfer side; and
the circuit board is in thermal communication with the first heat transfer side through the second heat transfer side.

3. The power tool of claim 2, wherein:
the motor defines a motor axis;
the circuit board includes at least one MOSFET; and
the second heat transfer side is directly between a first of the at least one MOSFET and the first heat transfer side in a plane orthogonal to the motor axis.

4. The power tool of claim 3, wherein:
the cooling zone includes a first cooling zone side to which the circuit board assembly is mounted and a second cooling zone side opposite to the first cooling zone side;
a plurality of fins extends from the second cooling zone side in a direction away from the circuit board assembly; and
at least a portion of the plurality of fins is coplanar with the circuit board assembly in the plane orthogonal to the motor axis.

5. The power tool of claim 4, wherein the plurality of fins is at least one of painted black and black anodized.

6. The power tool of claim 4, wherein:
the metallic housing incudes a generally circular portion and an extension:
the extension includes a generally planar portion facing the motor; and
the circuit board assembly is mounted to the generally planar portion.

7. The power tool of claim 6, wherein the plurality of fins extends from the second cooling zone side toward the motor.

8. The power tool of claim 6, wherein the plurality of fins extends from the second cooling zone side away from the motor.

9. The power tool of claim 6, further comprising:
a first handle supported by the metallic housing;
a second handle supported by the metallic housing;
the metallic housing is located between the first handle and the second handle;
at least a portion of the first handle is coplanar with the circuit board assembly in the plane orthogonal to the motor axis; and
at least a portion of the second handle is coplanar with the circuit board assembly in the plane orthogonal to the motor axis.

10. The power tool of claim 9, further comprising:
a fan driven by the motor and configured to generate an airflow within the metallic housing;
at least one vent located at a lower portion of the power tool and configured to allow air to flow from outside of the metallic housing through the at least one vent and into the metallic housing, the airflow comprising the air flowing through the at least one vent; and
the airflow comprising the air flowing through the at least one vent is directed by the at least one vent to flow through the plurality of fins or across the circuit board assembly from a lower portion of the circuit board assembly to an upper portion of the circuit board assembly.

11. The power tool of claim 10, the circuit board assembly further comprising:
a heat spreader plate including a base contact portion in thermal communication with a second of the at least one MOSFET, and including a cooling fin extending into the airflow.

12. A method of cooling a power tool comprising:
providing a metallic housing having a user-facing first side portion and a second side portion opposite the user-facing first side portion, the metallic housing defining a cooling zone in the second side portion opposite the user-facing first side portion;
mounting a circuit board assembly to the cooling zone such that the circuit board assembly is in thermal communication with the cooling zone with a motor positioned within the metallic housing at a location between the circuit board assembly and the user-facing first side portion;
generating heat with the circuit board assembly; and
transferring the generated heat to the cooling zone.

13. The method of claim 12, wherein:
the circuit board assembly includes a frame, a metal plate, and a circuit board;
the frame defines at least in part a cavity;
the metal plate is attached to the frame and has a first heat transfer side defining at least in part an outer surface of the circuit board assembly and a second heat transfer side facing toward the cavity;
the second heat transfer side is in thermal communication with the cooling zone through the first heat transfer side;
the circuit board is in thermal communication with the first heat transfer side through the second heat transfer side;
generating the heat with the circuit board assembly includes generating heat with at least one circuit board component; and
transferring the generated heat to the cooling zone includes transferring the heat generated by the at least one circuit board component from the circuit board to the first heat transfer side from the second heat transfer side.

14. The method of claim 13, wherein:
the motor defines a motor axis;
the circuit board includes at least one MOSFET;
the second heat transfer side is directly between the at least one MOSFET and the first heat transfer side in a plane orthogonal to the motor axis; and
the at least one circuit board component comprises the at least one MOSFET.

15. The method of claim 14, wherein:
the cooling zone includes a first cooling zone side to which the circuit board assembly is mounted and a second cooling zone side opposite to the first cooling zone side;
a plurality of fins extends from the second cooling zone side in a direction away from the circuit board assembly;
at least a portion of the plurality of fins is coplanar with the circuit board assembly in the plane orthogonal to the motor axis; and
the method further comprises transferring heat from the cooling zone using the plurality of fins.

16. The method of claim 15, wherein the plurality of fins is at least one of painted black and black anodized.

17. The method of claim 15, wherein:
the metallic housing incudes a generally circular portion and an extension:
the extension includes a generally planar portion facing the motor;
the circuit board assembly is mounted to the generally planar portion; and
transferring the generated heat to the cooling zone includes transferring the generated heat to the generally planar portion.

18. The method of claim 17, wherein:
transferring heat from the cooling zone using the plurality of fins includes transferring the heat from the cooling zone into a motor cavity of the metallic housing.

19. The method of claim 17, wherein:
transferring heat from the cooling zone using the plurality of fins includes transferring the heat from the cooling zone into an environment surrounding the metallic housing.

20. The method of claim 17, further comprising:
directing an airflow generated by a fan driven by the motor through the plurality of fins or across the circuit board assembly from a lower portion of the circuit board assembly to an upper portion of the circuit board assembly.
